(19) United States
(12) Patent Application Publication
(10) Pub. No.: US 2026/0156870 A1
(43) Pub. Date: Jun. 4, 2026

(54) THIN FILM TRANSISTOR, PIXEL STRUCTURE AND MANUFACTURING METHOD OF THIN FILM TRANSISTOR

(71) Applicant: AUO Corporation, Hsinchu City (TW)

(72) Inventor: Cheng-Wei Jiang, Hsinchu City (TW)

(73) Assignee: AUO Corporation, Hsinchu City (TW)

(21) Appl. No.: 18/974,794

(22) Filed: Dec. 10, 2024

(30) Foreign Application Priority Data
Dec. 4, 2024 (TW) 113146931

(51) Int. Cl. H10D 30/67; H10D 30/01; H10H 29/32; H10K 59/121

(52) U.S. Cl. CPC H10D 30/6736; H10D 30/0312; H10H 29/32; H10K 59/1213

(57) ABSTRACT

A thin film transistor includes a substrate, a gate, a semiconductor layer and a gate insulating layer. The gate is disposed on the substrate and has a top surface and side surface. The semiconductor layer is disposed on the substrate and includes a drain region, a channel region and a source region, and the gate overlaps the channel region. The contour of an upper surface of the gate insulating layer has a first surface, a second surface, a third surface and a fourth surface disposed in sequence to form a groove. The first surface overlaps the top surface, the second surface and third surface overlap the side surface, and the fourth surface overlaps the substrate. Also disclosed are a pixel structure including the thin film transistor and a manufacturing method of the thin film transistor.

### CROSS-REFERENCE TO RELATED APPLICATION

This application claims the priority benefit of Taiwan application serial no. 113146931, filed on Dec. 4, 2024. The entirety of the above-mentioned patent application is hereby incorporated by reference herein and made a part of this specification.

### BACKGROUND

### Technical Field

The present disclosure relates to a semiconductor element, a circuit structure, and a method of manufacturing a semiconductor element, and particularly relates to a thin film transistor, a pixel structure, and a method of manufacturing a thin film transistor.

### Description of Related Art

With the innovation of display technology, the requirements for brightness, performance, and resolution of display panels have gradually increased. Displays using self-luminous elements (for example, micro light-emitting diodes) have gradually become the focus of research and development by relevant manufacturers due to their advantages such as not requiring a backlight module and having high brightness and high contrast.

However, self-luminous elements are driven by thin film transistors on the active matrix substrate. If the light-emitting element is a current-driven element, the thin film transistor must also provide a larger current. For example, to meet the high current demand of micro light-emitting diodes (micro LEDs), thin film transistors also require better high electron mobility, lower critical dimension requirements, lower resistive capacitive delay, and large storage capacitance. However, the performance of current thin film transistors still needs to be improved.

### SUMMARY

The present disclosure provides a thin film transistor that may offer high current gain and have good electrical properties.

The present disclosure provides a pixel structure that may meet the high current requirements of self-luminous elements, and the self-luminous elements have high and uniform brightness. When used in displays, such pixel structure may improve the resolution, contrast, and brightness of the display screen.

The present disclosure provides a method of manufacturing a thin film transistor that may improve the production yield of thin film transistors.

An embodiment of the present disclosure provides a thin film transistor, which includes a substrate, a first gate, a first semiconductor layer and a first gate insulating layer. The first gate is disposed on the substrate and has a top surface and a side surface. The first semiconductor layer is disposed on the substrate and includes a drain region, a channel region and a source region, and the first gate overlaps the channel region. The first gate insulating layer is disposed between the first semiconductor layer and the first gate. An upper surface contour of the first gate insulating layer has a first surface, a second surface, a third surface and a fourth surface disposed in sequence to form a groove. The first surface overlaps the top surface, the second surface and third surface overlap the side surface, and the fourth surface overlaps the substrate. A thickness of the first gate insulating layer on the first surface is less than a thickness of the first gate insulating layer on the second surface, and a thickness of the first gate insulating layer increases from the third surface to the fourth surface.

An embodiment of the present disclosure provides a pixel structure, including a self-luminous element and multiple thin film transistors. At least one of these thin film transistors has the structure of the aforementioned thin film transistor. At least one of these thin film transistors is electrically connected to the self-luminous element, and the self-luminous element includes at least one of a micro light-emitting diode, a sub-millimeter light-emitting diode, and an organic light-emitting diode.

An embodiment of the present disclosure provides a method of manufacturing a thin film transistor, including forming a gate on a substrate, wherein the gate has a top surface and a side surface connected to the top surface; forming a gate insulating layer on the gate; etching the gate insulating layer to make the upper surface contour of the gate insulating layer have a first surface, a second surface, a third surface, and a fourth surface disposed in sequence to form a groove; forming a semiconductor layer so that the gate insulating layer is disposed between the semiconductor layer and the gate, wherein the first surface overlaps with the top surface, the second surface and the third surface overlap with the side surface, and the fourth surface overlaps with the substrate. The thickness of the gate insulating layer on the first surface is less than the thickness of the gate insulating layer on the second surface, and the thickness of the gate insulating layer increases from the third surface to the fourth surface.

To make the above-mentioned features and advantages of the present disclosure more evident and understandable, exemplary embodiments are presented below, with detailed explanations in conjunction with the accompanying drawings.

### BRIEF DESCRIPTION OF THE DRAWINGS

FIG. 1A is a cross-sectional schematic view of a thin film transistor according to an embodiment of the present disclosure. FIG. 1B is an enlarged schematic view of a region A1 in FIG. 1A. FIG. 1C is a top view of a partial structure of the thin film transistor in FIG. 1A.

FIG. 2A and FIG. 2B are cross-sectional schematic views of partial structures of a thin film transistor in a comparative example and an embodiment of the present disclosure, respectively.

FIG. 3A to FIG. 3E are cross-sectional schematic views of partial manufacturing processes of a thin film transistor according to an embodiment of the present disclosure.

FIG. 4 is a circuit diagram of a pixel structure according to an embodiment of the present disclosure.

FIG. 5A to FIG. 5C are cross-sectional schematic views of thin film transistors according to multiple embodiments of the present disclosure.

FIG. 6A is a cross-sectional schematic view of a thin film transistor according to an embodiment of the present disclosure.

FIG. 6B is an enlarged schematic view of a region A2 in FIG. 6A.

FIG. 7 is a cross-sectional schematic view of a thin film transistor according to an embodiment of the present disclosure.

FIG. 8 is a cross-sectional schematic view of a partial region of a pixel structure according to an embodiment of the present disclosure.

### DESCRIPTION OF THE EMBODIMENTS

Reference will now be made in detail to exemplary embodiments of the disclosure, examples of which are illustrated in the accompanying drawings. Wherever possible, the same reference numbers are used in the drawings and the description to refer to the same or similar parts.

It should be understood that when an element such as a layer, film, region, or substrate is referred to as being “on” or “connected to” another element, it may be directly on or connected to the other element, or intervening elements may also be present. In contrast, when an element is referred to as being “directly on” or “directly connected to” another element, there are no intervening elements present. As used herein, “connected” may refer to physical and/or electrical connection. Furthermore, “electrical connection” or “coupling” may exist between two elements even when other elements are present between them.

The terms “about,” “approximately,” or “substantially” as used herein include the stated value and average values within an acceptable deviation range determined by ordinary skilled persons in the field, considering the specific quantity of the measurements discussed and errors associated with the measurements (i.e., limitations of the measurement system). For example, “about” may indicate within one or more standard deviations of the stated value, or within ±30%, ±20%, ±10%, ±5%. Furthermore, “about,” “approximately,” or “substantially” as used herein may be selected with a more acceptable deviation range or standard deviation according to optical properties, etching properties, or other properties, rather than applying one standard deviation to all properties.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

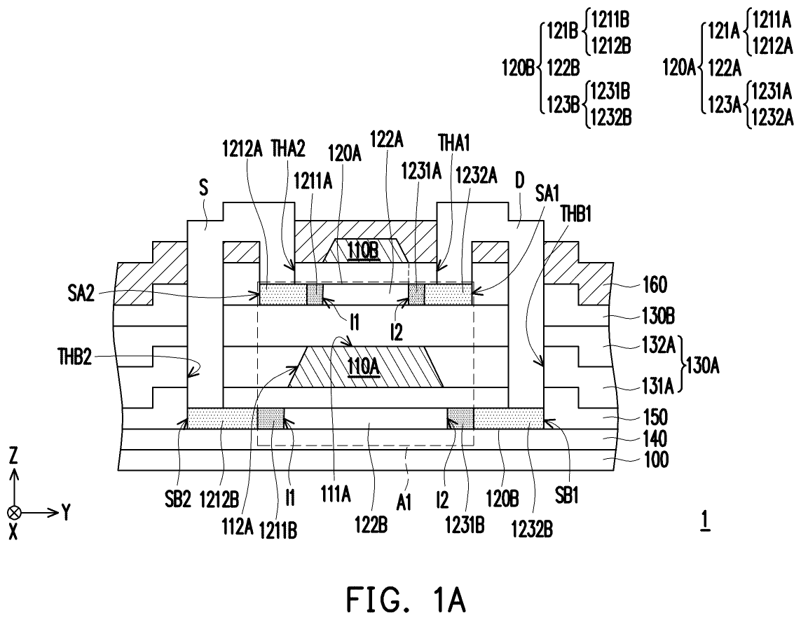

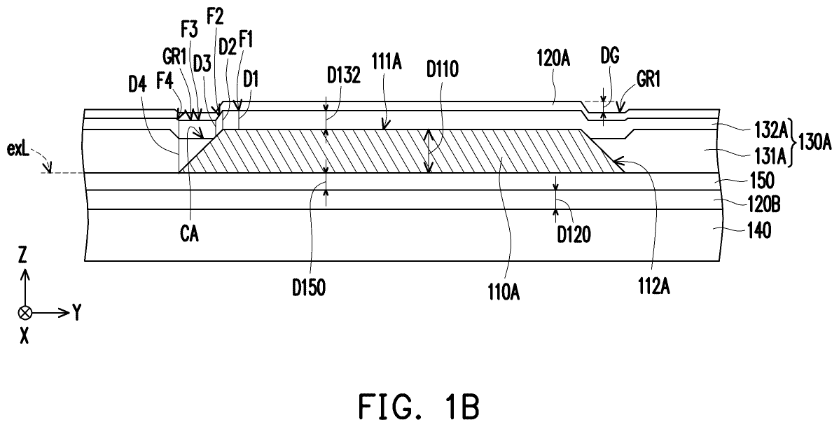

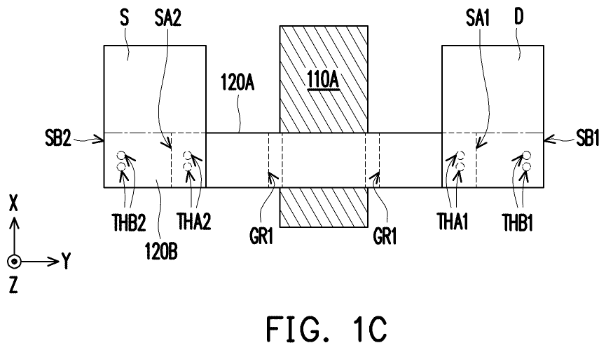

FIG. 1A is a cross-sectional schematic view of a thin film transistor according to an embodiment of the present disclosure. FIG. 1B is an enlarged schematic view of a region A1 in FIG. 1A. FIG. 1C is a top view of a partial structure of the thin film transistor in FIG. 1A. Please refer first to FIG. 1A, the thin film transistor 1 includes a substrate 100, a first gate 110A, a second gate 110B, a first semiconductor layer 120A, a second semiconductor layer 120B, a first gate insulating layer 130A, a second gate insulating layer 130B, a buffer layer 140, an insulating layer 150, a blocking layer 160, a source S and a drain D.

In this embodiment, the material of the substrate 100 may be glass, quartz, organic polymer, opaque/reflective material (for example: conductive material, wafer, ceramic, or other applicable materials), or other applicable materials. It should be noted that, unless otherwise specified in the following text, direction Z may be the normal direction of the substrate 100, and may also represent the thickness directions of various film layers, while the plane containing direction X and direction Y may be the plane of the substrate 100.

The first gate 110A has a top surface 111A and a side surface 112A. The side surface 112A may have a gradually varying thickness, for example, as direction Y increases, the film thickness of the side surface 112A in direction Z gradually decreases. On the other hand, based on considerations of conductivity, the first gate 110A, the second gate 110B, the source S and the drain D are generally made of metal material. However, the present disclosure is not limited to this. According to other embodiments, the first gate 110A, the second gate 110B, the source S and the drain D may also use other conductive materials. For example: alloys, nitrides of metal materials, oxides of metal materials, oxynitrides of metal materials, or stacked layers of metal materials with other conductive materials. The present disclosure is not limited to this.

The first semiconductor layer 120A is disposed on the substrate 100. Furthermore, in this embodiment, the first semiconductor layer 120A is disposed on the first gate 110A. In addition, the first semiconductor layer 120A includes a first source region 121A, a first channel region 122A, and a first drain region 123A, and the first gate 110A overlaps with the first channel region 122A. Similarly, the second semiconductor layer 120B is disposed on the substrate 100. Moreover, the second semiconductor layer 120B includes a second source region 121B, a second channel region 122B, and a second drain region 123B, with the second channel region 122B overlapping the first gate 110A. In this embodiment, the first semiconductor layer 120A and the second semiconductor layer 120B are, for example, semiconductor materials of polysilicon thin film, and include doped regions with different carrier doping concentrations (to be explained later), but the present disclosure is not limited to this.

On the other hand, the first gate insulating layer 130A is disposed between the first semiconductor layer 120A and the first gate 110A. In this embodiment, the material of the first gate insulating layer 130A may preferably be inorganic material (for example: silicon oxide, silicon nitride, silicon oxynitride, or a stacked layer of at least two of the above materials). The materials of the second gate insulating layer 130B and the insulating layer 150 may be the same as or different from the material of the first gate insulating layer 130A; the present disclosure is not limited to this. Furthermore, in this embodiment, the first gate insulating layer 130A may include a first sublayer 131A and a second sublayer 132A, with the first sublayer 131A disposed between the first gate 110A and the second sublayer 132A. The material of the first sublayer 131A may be the same as or different from the material of the second sublayer 132A. In some embodiments, the second sublayer 132A may serve as another buffer layer, but the present disclosure is not limited to this. In other embodiments, the first gate insulating layer 130A may be only a single-layer structure or may be stacked with more other sublayers.

Please refer to both FIG. 1A and FIG. 1B. It is worth mentioning that the contour (or it may also be understood as the surface contour of the second sublayer 132A in the direction Z away from the first gate 110A) of the upper surface of the first gate insulating layer 130A away from the first gate 110A has a first surface F1, a second surface F2, a third surface F3, and a fourth surface F4 arranged in sequence to form a groove GR1. The first surface F1 overlaps with the top surface 111A, the second surface F2 and the third surface F3 overlap with the side surface 112A, and the fourth surface F4 overlaps with the substrate 100 but does not overlap with the first gate 110A. Moreover, the thickness D1 of the first gate insulating layer 130A on the first surface F1 is less than the thickness D2 of the first gate insulating layer 130A on the second surface F2, and the thickness of the first gate insulating layer 130A increases from the third surface F3 to the fourth surface F4. It should be explained that the definition of thicknesses D1 to D4 here is the film thickness of the first gate insulating layer 130A at different positions in the direction Z. For example, the thickness D1 may be the vertical distance from the upper surface of the second sublayer 132A away from the first gate 110A to the top surface 111A, or the thickness D1 may be substantially the thickness D132; the thickness D2 may be the vertical distance from the second surface F2 of the groove GR1 to the side surface 112A; the thickness D3 may be the vertical distance from the third surface F3 of the groove GR1 to the side surface 112A; the thickness D4 may be the vertical distance from the fourth surface F4 of the groove GR1 to the lower surface of the first sublayer 131A. Or from another perspective, the lower surface of the first gate 110A has an extension plane exL in the direction Y, and the thickness D4 may also be defined as the vertical distance between the fourth surface F4 and the extension plane exL.

In detail, during the process of manufacturing the first gate 110A and the first gate insulating layer 130A, the thickness of the first gate insulating layer 130A may be reduced by an etching process, and the different properties of the materials of the first gate 110A and the first gate insulating layer 130A may be utilized to make the thickness of the first gate insulating layer 130A above the top surface 111A different from the thickness of the first gate insulating layer 130A above the side surface 112A. In this way, the thickness D1 (or thickness D132) of the first gate insulating layer 130A may be reduced, and the groove GR1 overlapping with the side surface 112A may be formed on the upper surface of the first gate insulating layer 130A. By this means, the first semiconductor layer 120A above the first gate 110A may be formed on a relatively flat surface, reducing the risk of disconnection of the first semiconductor layer 120A that might cause the transistor to fail. From another perspective, the yield and electrical properties of the thin film transistor 1 may be improved.

It is worth mentioning that, in the implementation where the first sublayer 131A and the second sublayer 132A are of different materials, a boundary between the first sublayer 131A and the second sublayer 132A may be observed through measuring instruments (such as Scanning Electron Microscope, SEM). Furthermore, the first sublayer 131A may be etched before disposing the second sublayer 132A, thus it is possible to observe that the first sublayer 131A covers the side surface 112A of the first gate 110A, and the first sublayer 131A forms a concave structure CA on the side surface 112A of the first gate 110A, where the concave structure CA overlaps with the groove GR1 (as shown in FIG. 1B).

Moreover, during the etching process, the first sublayer 131A above the first gate 110A may be completely etched, so that a part (or all) of the top surface 111A is not covered by the first sublayer 131A. In other words, the second sublayer 132A may contact a part (or all) of the top surface 111A of the first gate 110A, contact the concave structure CA of the first sublayer 131A, and contact the upper surface of the first sublayer 131A that does not overlap with the first gate 110A. Of course, the present disclosure is not limited to this. In other implementations not illustrated, the first sublayer 131A may also cover the top surface 111A.

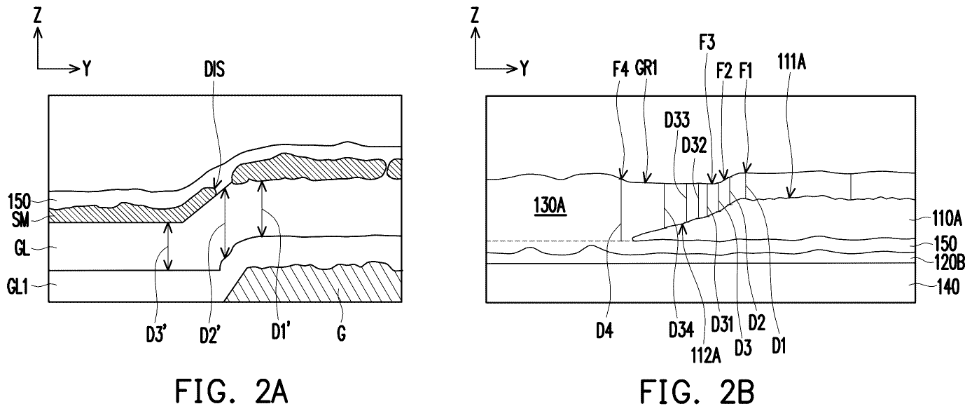

FIG. 2A and FIG. 2B are cross-sectional schematic views of partial structures of thin film transistors in a comparative example and an embodiment of the present disclosure. Please first refer to FIG. 2A, which shows the result of successive stacking of various film layers without etching grooves. In this case, directly depositing the gate insulating layer GL1 and the gate insulating layer GL2 will cause a larger discontinuity formed by the gate insulating layer GL1 and the gate insulating layer GL2. Before forming the semiconductor layer SM, it is required for the amorphous silicon material of the semiconductor layer SM to undergo Excimer Laser Annealing (ELA) to form Low-temperature polycrystalline silicon (LTPS). At this time, the material of the molten semiconductor layer SM is easily affected by gravity and surface unevenness, resulting in disconnection (for example, forming a disconnected region DIS), which reduces the yield of the thin film transistor or even causes failure. In addition, if no groove is etched, from the top surface of the thin film transistor towards the direction outside the thin film transistor, the film thickness of the gate insulating layer will first increase on the inclined surface and then return to its original thickness. For example, the thickness D1′ of the gate insulating layer GL2 on the top surface of the gate G is about 3104 (Å); the thickness D2′ of the gate insulating layer GL2 on the inclined surface of the gate G is about 3680 (Å); the thickness D3′ of the gate insulating layer GL2 in the region outside the gate G is about 3104 (Å) (which may also be interpreted as the distance from the upper surface of the gate insulating layer GL2 to the upper surface of the gate insulating layer GL1). Furthermore, in the case where no groove is etched, the thickness of the gate insulating layer above the side surface of the gate G will maintain a constant value.

TABLE 1

| Thickness | D1 | D2 | D3 | D31 | D32 | D33 | D34 | D4 |
|---|---|---|---|---|---|---|---|---|
| Thickness (Å) | 1438 | 1560 | 1483 | 1820 | 1973 | 2141 | 2462 | 3150 |
| The ratio | 8% | −5% | 23% | 8% | 9% | 15% | 28% | 8% |
| of change | | | | | | | | |
| at different | | | | | | | | |
| positions | | | | | | | | |

Table 1 lists the film thicknesses and change trends of the first gate insulating layer 130A at different positions. Please refer to FIG. 2B and Table 1 simultaneously, which show the result of successive stacking of various film layers with etched groove GR1. In this implementation, the thickness D1 (about 1438 (Å)) of the first gate insulating layer 130A on the first surface F1 is less than the thickness D2 (about 1560 (Å)) of the first gate insulating layer 130A on the second surface F2. Moreover, the thickness D3 (about 1483 (Å)) of the first gate insulating layer 130A on the third surface F3 is less than the thickness D2. On the other hand, on the third surface F3 and the fourth surface F4 of the groove GR1, the thickness (for example, from thickness D3, thicknesses D31 to D34 to thickness D4) of the first gate insulating layer 130A increases from the third surface F3 to the fourth surface F4 until the first gate insulating layer 130A does not overlap with the first gate 110A, then the thickness of the first gate insulating layer 130A maintains a constant value. In other words, in this implementation, in the negative direction Y, the thickness of the first gate insulating layer 130A above the side surface 112A gradually increases in its change trend.

As mentioned above, in some embodiments, the groove GR1 may have an appropriate depth, for example, the depth DG of the groove GR1 may be greater than 0 micrometers and less than half of the thickness D110 of the first gate 110A. In some embodiments, the depth DG of the groove GR1 may be less than the maximum thickness D120 of the second semiconductor layer 120B. On the other hand, since the thickness of the first gate insulating layer 130A may be lower, the film thickness of the first gate 110A may be larger to have good conductivity, and maintain the flatness of the upper surface of the first gate insulating layer 130A. For example, in some embodiments, the thickness D110 of the first gate 110A may be greater than 1000 (Å).

Please refer again to FIG. 1A and FIG. 1B, the blocking layer 160 of the thin film transistor 1 may be disposed on the second gate insulating layer 130B, and cover and contact the second gate 110B. The blocking layer 160, for example, is an Inorganic Barrier Passivation Layer (IOBP) formed of inorganic material, used for surface treatment and may protect the underlying elements or layers (for example, the second gate 110B) from etching solution corrosion and contamination during the process. In addition, the insulating layer 150 is disposed between the second semiconductor layer 120B and the first gate 110A, configured to electrically isolate the first gate 110A from the second semiconductor layer 120B. Moreover, since the film thickness of the first gate insulating layer 130A is further reduced through the etching process, the thickness D150 of the insulating layer 150 may be greater than the thickness D132 of the first gate insulating layer 130A on the top surface 111A.

Please continue to refer to FIG. 1A, on the other hand, the first source region 121A of the first semiconductor layer 120A may include a first lightly-doped region 1211A and a first heavily-doped region 1212A, the first drain region 123A may include a second lightly-doped region 1231A and a second heavily-doped region 1232A. Furthermore, in the direction Y, the first lightly-doped region 1211A is disposed between the first heavily-doped region 1212A and the first channel region 122A, the first channel region 122A is disposed between the first lightly-doped region 1211A and the second lightly-doped region 1231A, the second lightly-doped region 1231A is disposed between the first channel region 122A and the second heavily-doped region 1232A, and there is a boundary I1 between the first lightly-doped region 1211A and the first channel region 122A, there is a boundary I2 between the first channel region 122A and the second lightly-doped region 1231A.

In detail, the doping concentration of the first lightly-doped region 1211A and the first heavily-doped region 1212A may be optionally different (for example: the doping concentration of the first lightly-doped region 1211A is less than the doping concentration of the first heavily-doped region 1212A), but the present disclosure is not limited to this. It should be noted that, in practical application, the boundary I1 and the boundary I2 are not visible, the boundary I1 and the boundary I2 are virtual boundaries between two regions with different doping concentrations. For example, instruments may be used to analyze the doping concentrations of the first lightly-doped region 1211A and the first channel region 122A, and the position where the doping concentration changes abruptly is the position of the virtual boundary (i.e., the boundary I1).

Similarly, the second source region 121B of the second semiconductor layer 120B may include a first lightly-doped region 1211B and a first heavily-doped region 1212B, the second drain region 123B may include a second lightly-doped region 1231B and a second heavily-doped region 1232B. Furthermore, in the direction Y, the first lightly-doped region 1211B is disposed between the first heavily-doped region 1212B and the second channel region 122B, the second channel region 122B is disposed between the first lightly-doped region 1211B and the second lightly-doped region 1231B, the second lightly-doped region 1231B is disposed between the second channel region 122B and the second heavily-doped region 1232B, and there is also a boundary I1 between the second channel region 122B and the first lightly-doped region 1211B, there is also a boundary I2 between the second channel region 122B and the second lightly-doped region 1231B. The configuration relationship of various doped regions in the second semiconductor layer 120B may be the same as the configuration relationship of the first semiconductor layer 120A, which will not be repeated here.

FIG. 1C is a top view of a partial structure of the thin film transistor of FIG. 1A. Please refer again to FIG. 1A and FIG. 1C. On the other hand, the second gate insulating layer 130B is disposed on the first semiconductor layer 120A, and the second gate 110B is disposed on the second gate insulating layer 130B. Specifically, in this embodiment, the second gate insulating layer 130B is disposed between the second gate 110B and the first semiconductor layer 120A. In addition, the buffer layer 140 is disposed between the substrate 100 and the second semiconductor layer 120B, and the second semiconductor layer 120B is disposed between the substrate 100 and the first gate 110A. In this embodiment, the material of the buffer layer 140 may be inorganic material (for example: silicon oxide, silicon nitride, silicon oxynitride, or a stacked layer of at least two of the above materials), organic material or a combination of the above, to facilitate the epitaxy or growth of various film layers above the buffer layer 140 (for example, the growth of the second semiconductor layer 120B).

On the other hand, in this embodiment, the drain D may be directly electrically connected to the first side SA1 of the first semiconductor layer 120A and the first side SB1 of the second semiconductor layer 120B. The source S may be directly electrically connected to the second side SA2 of the first semiconductor layer 120A and the second side SB2 of the second semiconductor layer 120B, and the first side SA1 and the second side SA2 of the first semiconductor layer 120A may be two sides opposite to each other in the direction Y, the first side SB1 and the second side SB2 of the second semiconductor layer 120B may be two sides opposite to each other in the direction Y.

Specifically, the drain D may be directly electrically connected to the first drain region 123A of the first semiconductor layer 120A through the through hole THA1 penetrating the blocking layer 160 and the second gate insulating layer 130B, and directly electrically connected to the second drain region 123B of the second semiconductor layer 120B through the through hole THB1 penetrating the blocking layer 160, the second gate insulating layer 130B, the first gate insulating layer 130A and the insulating layer 150. Similarly, the source S may be directly electrically connected to the first source region 121A of the first semiconductor layer 120A through the through hole THA2 penetrating the blocking layer 160 and the second gate insulating layer 130B, and directly electrically connected to the second source region 121B of the second semiconductor layer 120B through the through hole THB2 penetrating the blocking layer 160, the second gate insulating layer 130B, the first gate insulating layer 130A and the insulating layer 150. From another perspective, the thin film transistor 1 may also be a multi-channel thin film transistor (Multi-channel TFT) that are interconnected, thereby effectively increasing the on-current flowing through the thin film transistor 1.

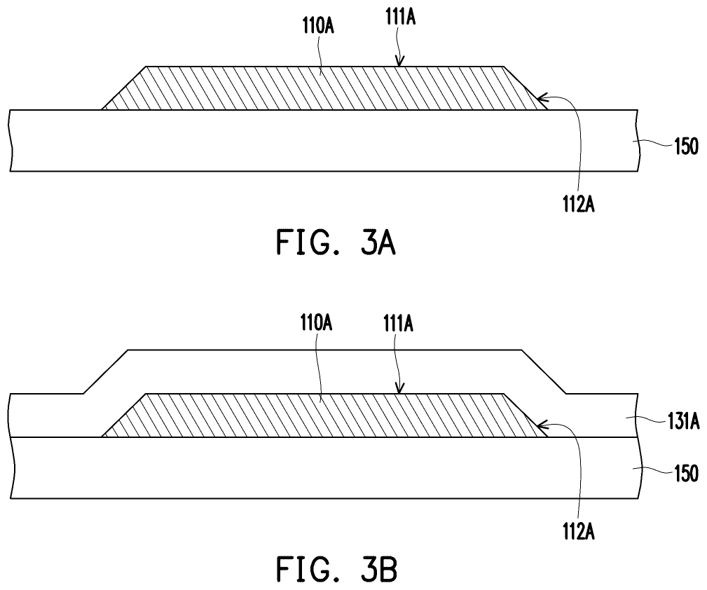

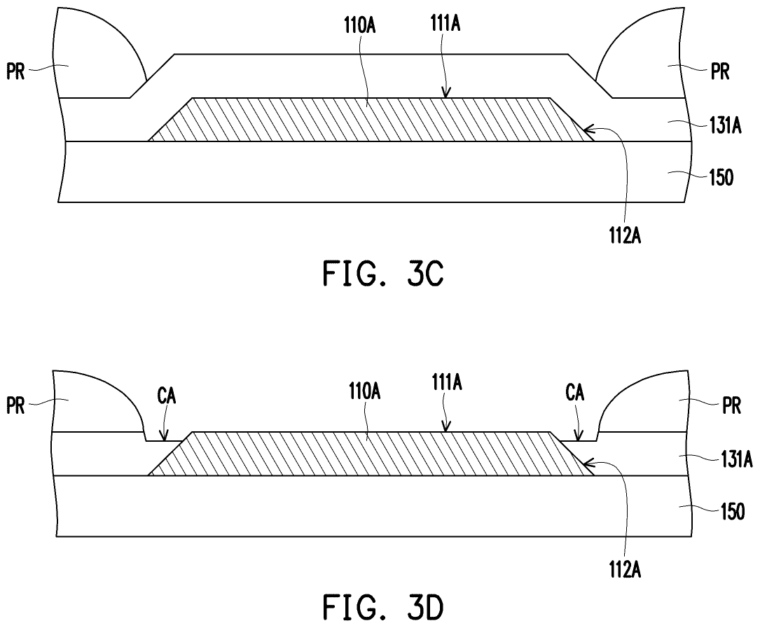

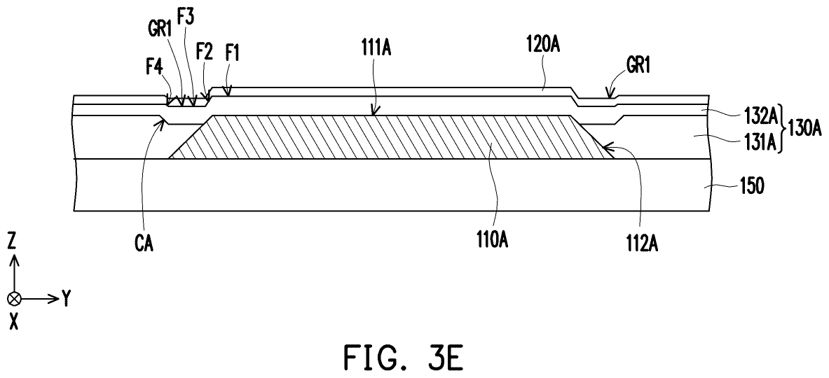

FIG. 3A to FIG. 3E are cross-sectional schematic views of a partial manufacturing process of a thin film transistor according to an embodiment of the present disclosure. Please first refer to FIG. 3A, a substrate 100 is first provided, and a buffer layer 140, a second semiconductor layer 120B, an insulating layer 150, and a first gate 110A are formed in sequence on the substrate 100. The first gate 110A has a top surface 111A and a side surface 112A connected thereto. The method of forming the above-mentioned film layers may be physical vapor deposition (PVD), chemical vapor deposition (CVD), or atomic layer deposition (ALD), and formed using photolithography process. The present disclosure is not limited to this. It should be noted that in FIG. 3A, only the first gate 110A and part of the insulating layer 150 are schematically drawn. The relative relationships of the above-mentioned elements may be referenced to the structure of FIG. 1 described above, which will not be repeated here.

Referring to FIG. 3B, a gate insulating layer is then formed on the first gate 110A. For example, the method of forming the previous elements may be adopted to directly form inorganic insulating material on the insulating layer 150 and the first gate 110A to form the first sublayer 131A mentioned above. It should be noted that in the implementation where the gate insulating layer is a single insulating layer, the same insulating material may also be deposited on the insulating layer 150 and the first gate 110A in this step. The present disclosure is not limited to this.

Referring to FIG. 3C, the gate insulating layer is then etched. For example, a photoresist layer PR may be formed on the first sublayer 131A by using coating or spinning, as well as baking and developing processes. The photoresist layer PR may be patterned so that a part of the first sublayer 131A overlapping with the first gate 110A is not covered by the photoresist layer PR. Then referring to FIG. 3D, an etching process is performed on the first sublayer 131A, so that the first sublayer 131A exposes a part of the top surface 111A and a part of the side surface 112A. The etching process may be wet etching or dry etching, and the present disclosure is not limited to this. For example, an etchant with different etching rates for the first sublayer 131A and the first gate 110A may be used, so that a part of the first sublayer 131A adjacent to the side surface 112A and not covered by the photoresist layer PR is eroded more, forming a concave structure CA adjacent to the side surface 112A. At this point, the thickness of the first sublayer 131A (or it may be interpreted as part of the first gate insulating layer 130A) is reduced.

Then referring to FIG. 3E, the second sublayer 132A may be formed on the first sublayer 131A to form the first gate insulating layer 130A. Due to the concave structure CA of the first sublayer 131A, after forming the second sublayer 132A, the contour of the upper surface (i.e., the surface of the second sublayer 132A away from the first sublayer 131A) of the first gate insulating layer 130A may have a first surface F1, a second surface F2, a third surface F3, and a fourth surface F4 arranged in sequence to form a groove GR1. The groove GR1 may be located on both side surfaces 112A of the first gate 110A in the direction Y. The first semiconductor layer 120A is also formed, with the second sublayer 132A disposed between the first semiconductor layer 120A and the first gate 110A. At this point, the setup of the first gate insulating layer 130A and the first semiconductor layer 120A mentioned earlier is preliminarily completed. The related features and explanations may be referenced to the previous paragraphs and will not be repeated here. As the thickness of the first gate insulating layer 130A is reduced and planarized, the step difference on the upper surface of the first gate insulating layer 130A may be mitigated, allowing the first semiconductor layer 120A to be formed on a relatively flat surface, indirectly improving the production yield of the first semiconductor layer 120A and the thin film transistor 1.

It must be explained here that the following implementation example continues to use the reference numerals and partial content from the previous implementation example, where the same numerals are used to represent the same or similar elements, and explanations of identical technical content are omitted. For explanations of the omitted parts, please refer to the previous implementation example. The following implementation example will not repeat these details.

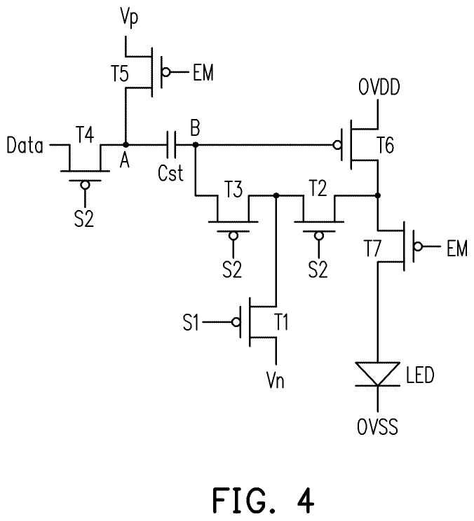

FIG. 4 is a circuit diagram of a pixel structure according to an embodiment of the present disclosure. Referring to FIG. 4, the pixel structure 10 includes a capacitor Cst, a light-emitting element LED, and a first transistor T1, a second transistor T2, a third transistor T3, a fourth transistor T4, a fifth transistor T5, a sixth transistor T6, and a seventh transistor T7. In this embodiment, the first transistor T1 to the seventh transistor T7 may be P-type transistors, but the present disclosure is not limited to this. In other embodiments, the first transistor T1 to the seventh transistor T7 may be N-type transistors. The light-emitting element LED has an anode terminal and a cathode terminal receiving the low voltage OVSS of the system. The light-emitting element LED may be at least one of a micro light-emitting diode, a sub-millimeter light-emitting diode, and an organic light-emitting diode. The capacitor Cst has an A terminal and a B terminal, with the A terminal electrically connected to the fourth transistor T4 and the fifth transistor T5, and the B terminal electrically connected to the third transistor T3 and the sixth transistor T6, which means the pixel structure 10 has a 7T1C structure. In other embodiments, the pixel structure may have a 2T1C structure, a 3T1C structure, a 3T2C structure, a 4T1C structure, a 4T2C structure, a 5T1C structure, a 5T2C structure, a 6T1C structure, a 6T2C structure, a 7T2C structure, or any possible pixel structure to drive the light-emitting element LED. The present disclosure is not limited to these.

The source of the first transistor T1 is electrically connected between the second transistor T2 and the third transistor T3, for example, electrically connected to the drain of the third transistor T3 and the source of the second transistor T2. The gate of the first transistor T1 may receive a first scan signal S1, and the drain of the first transistor T1 may receive a first reference voltage Vn.

The source of the second transistor T2 may be electrically connected to the drain of the third transistor T3, and the drain of the second transistor T2 may be electrically connected between the sixth transistor T6 and the seventh transistor T7, for example, electrically connected to the drain of the sixth transistor T6 and the source of the seventh transistor T7. The source of the third transistor T3 is electrically connected to the B terminal of the capacitor Cst. The gate of the second transistor T2 and the gate of the third transistor T3 may receive a second scan signal S2. It is particularly noted that the first scan signal S1 and the second scan signal S2 may be transmitted separately by different scan lines in a display (not shown). The first scan signal S1 and the second scan signal S2 may be voltage signals with the same waveform and intensity but different phases, to drive corresponding transistors sequentially in different timings. The present disclosure is not limited to this.

Please continue to refer to FIG. 4, the source of the fourth transistor T4 receives a data voltage Data, the drain of the fourth transistor T4 is electrically connected to the A terminal of the capacitor Cst, and the gate of the fourth transistor T4 receives the second scan signal S2. The source of the fifth transistor T5 receives a second reference voltage Vp, and the drain of the fifth transistor T5 is electrically connected to the A terminal of the capacitor Cst. The data voltage Data may be transmitted by a data line in the display (not shown), therefore the source, gate, and drain of the fourth transistor T4 may be directly electrically connected to the data line, scan line, and the fifth transistor T5, respectively. From another perspective, the fourth transistor T4 may also be defined as a switching thin film transistor, but the present disclosure is not limited to this.

The source of the sixth transistor T6 receives a system high voltage OVDD, the drain of the sixth transistor T6 is electrically connected to the source of the seventh transistor T7, and the gate of the sixth transistor T6 is electrically connected to the B terminal of the capacitor Cst. The source of the seventh transistor T7 may be directly electrically connected to the drain of the sixth transistor T6, the drain of the seventh transistor T7 is electrically connected to the anode terminal of the light-emitting element LED, and the gate of the seventh transistor T7 receives a light-emitting signal EM.

The pixel structure 10 may operate sequentially in a first period, a second period, and a third period, wherein the second period includes a preset time t1, the preset time t1 is immediately following the first period (i.e., at the beginning of the second period) and is less than the second period. During the first period, the first transistor T1 receives the first scan signal S1 and is in an on state, while the second transistor T2, the third transistor T3, the fourth transistor T4, the fifth transistor T5, and the seventh transistor T7 are in an off state; during the second period, the second transistor T2, the third transistor T3, and the fourth transistor T4 receive the second scan signal S2 and are in an on state, the first transistor T1 continues to be in an on state during the preset time t1 of the second period; during the third period, the first transistor T1, the second transistor T2, the third transistor T3, and the fourth transistor T4 are in an off state.

When in the first period, the first transistor T1 receives the first scan signal S1 and is in an on state, therefore the signal of the first reference voltage Vn may be transmitted to the source of the first transistor T1. When in the preset time t1 of the second period, the second transistor T2, the third transistor T3, and the fourth transistor T4 are in an on state, therefore the signal of the data voltage Data may be transmitted to the A terminal of the capacitor Cst, and the first reference voltage Vn may be transmitted to the B terminal of the capacitor Cst. Then, when the pixel structure 10 is in the second period but beyond the preset time t1, the first transistor T1 is in an off state but the second transistor T2, the third transistor T3, and the fourth transistor T4 are still in an on state, at this time the potential of the gate of the sixth transistor T6 is equal to the high voltage OVDD minus the threshold voltage Vth, that is (OVDD-Vth).

When in the third period, the second transistor T2, the third transistor T3, and the fourth transistor T4 are in an off state, the fifth transistor T5 and the seventh transistor T7 receive the light-emitting signal EM and are in an on state. At this time, the potential of the A terminal of the capacitor Cst changes from the data voltage Data to the second reference voltage Vp, with the change represented as (Vp-Data). Therefore, the potential of the B terminal of the capacitor Cst will change from (OVDD-Vth) in the second period to (OVDD-Vth)+(Vp-Data). According to the following relationship equation (1) of the current (Id) of the transistor: Id=K(Vs−Vg−|Vth|)²; where K is a constant related to the transistor structure, Vg is the gate voltage of the transistor, which for the sixth transistor T6 is (OVDD-Vth)+(Vp-Data); Vs is the voltage at the source, which for the sixth transistor T6 is the high voltage OVDD. By inputting the value of the high voltage OVDD into Vs in equation (1), and inputting the value of (OVDD-Vth)+(Vp-Data) into Vg in equation (1), Id=K(Data-Vp)² may be obtained. Since the light-emitting element LED is driven by the current (i.e., Id) flowing through the sixth transistor T6 when the sixth transistor T6 is in an on state, the sixth transistor T6 may also be defined as a driving thin film transistor. The current (i.e., Id) flowing through the seventh transistor T7 enables the light-emitting element LED to emit light, therefore the seventh transistor T7 may also be defined as a light-emitting thin film transistor.

As mentioned above, from equation (1) and the inference, it may also be known that the brightness of the light-emitting element LED will not be affected by the threshold voltage Vth of the sixth transistor T6, enabling the display adopting the pixel structure 10 to have uniform brightness. Moreover, in the pixel structure 10, since the current flowing through the sixth transistor T6 and the seventh transistor T7 is relatively large, at least one of the sixth transistor T6 and the seventh transistor T7 may be manufactured using the thin film transistor 1 of this embodiment, which may have advantages such as high current gain, reduced cross-voltage, and providing high current. When the light-emitting element LED is a micro light-emitting diode, the light-emitting element LED may exhibit the advantage of high brightness while maintaining good stability.

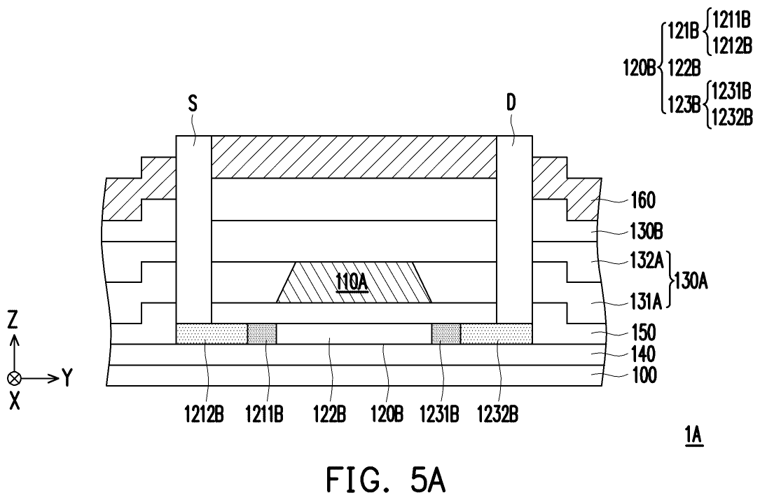

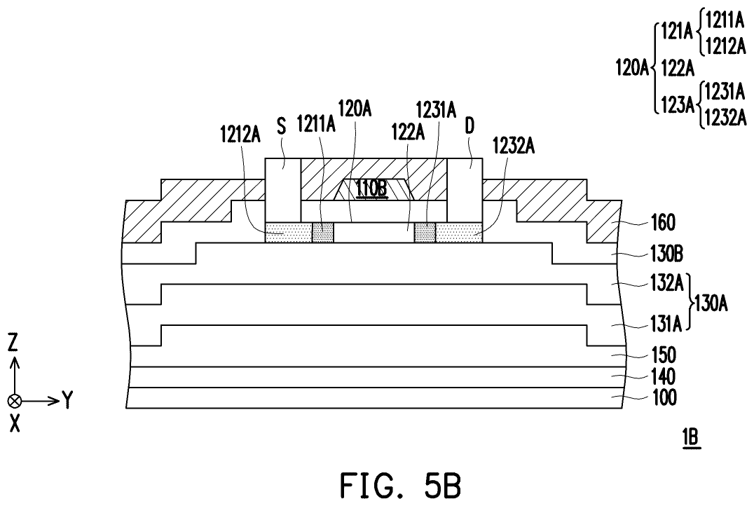

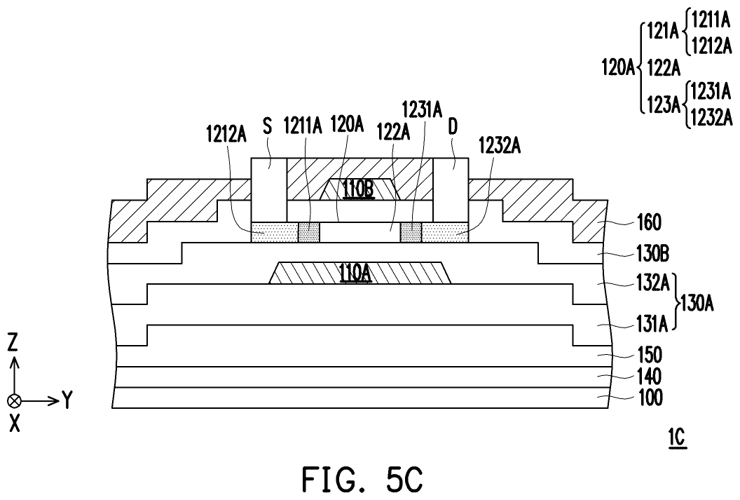

FIG. 5A to FIG. 5C are cross-sectional schematic views of thin film transistors of multiple embodiments of the present disclosure. Please refer to FIG. 5A, the thin film transistor 1A resembles the aforementioned thin film transistor 1, with the main difference being that in the direction Z, the thin film transistor 1A may include the buffer layer 140, the second semiconductor layer 120B, the insulating layer 150, the first gate 110A, the first gate insulating layer 130A, and the second gate insulating layer 130B arranged in sequence from the substrate 100 to the blocking layer 160 without setting up the second gate 110B.

Please refer to FIG. 5B, the thin film transistor 1B resembles the aforementioned thin film transistor 1, with the main difference being that in the direction Z, the thin film transistor 1B may include the buffer layer 140, the insulating layer 150, the first gate insulating layer 130A, the first semiconductor layer 120A, the second gate insulating layer 130B and the second gate 110B arranged in sequence from the substrate 100 to the blocking layer 160 without setting up the first gate 110A and the second semiconductor layer 120B.

Please refer again to FIG. 5C, the thin film transistor 1C resembles the aforementioned thin film transistor 1, with the main difference being that in the direction Z, the thin film transistor 1C may include the buffer layer 140, the insulating layer 150, the first sublayer 131A, the first gate 110A, the second sublayer 132A, the first semiconductor layer 120A, the second gate insulating layer 130B and the second gate 110B arranged in sequence from the substrate 100 to the blocking layer 160 without setting up the second semiconductor layer 120B. In other words, the thin film transistor 1C may be a dual-gate type thin film transistor. Although not illustrated in the embodiments of FIG. 5B to FIG. 5C, the first gate insulating layer 130A may also be formed with the groove GR1 structure as shown in FIG. 1B on the side surface of the first gate 110A. The relevant content may be referenced to the aforementioned paragraphs and will not be repeated here.

The aforementioned thin film transistors 1A to 1C may all be disposed in the same pixel structure 10 and applied to different types of transistors. For example, in FIG. 4, the first transistor T1, the second transistor T2, the third transistor T3, the fourth transistor T4, and the fifth transistor T5 may all adopt the structure design of the thin film transistor 1B on the upper layer, while the sixth transistor T6 and seventh transistor T7 may both be the structure design of thin film transistor 1A on the lower layer. In addition to designing the sixth transistor T6 and seventh transistor T7 with a larger size structure to meet their high current supply requirements, the structure of different transistors located in different layers may also effectively reduce the occupied area of the pixel structure 10 on the substrate 100. When the pixel structure 10 is applied to a display panel (not illustrated), it is also possible to increase the pixel density (PPI) and resolution of the display panel. Of course, the present disclosure is not limited to this.

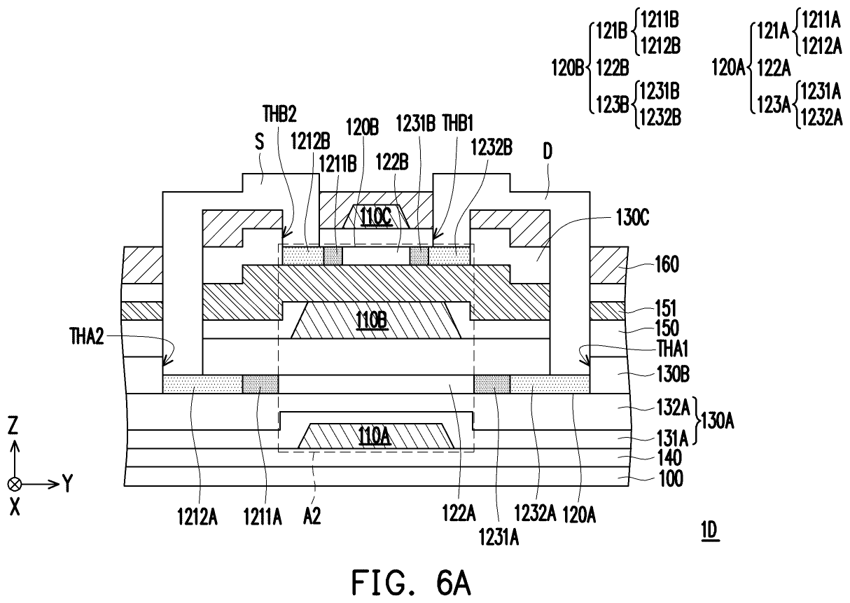

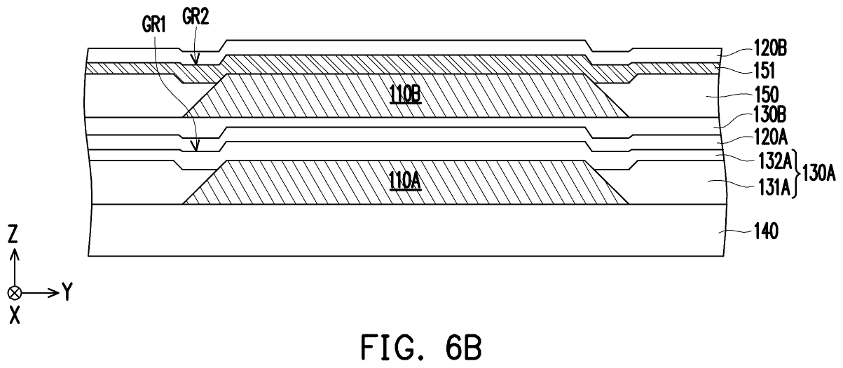

FIG. 6A is a cross-sectional schematic view of a thin film transistor according to an embodiment of the present disclosure. FIG. 6B is an enlarged schematic view of the region A2 in FIG. 6A. Please first refer to FIG. 6A, the thin film transistor 1D resembles the aforementioned thin film transistor 1, with the main difference being that: the thin film transistor 1D further includes an insulating layer 151 disposed between the second gate 110B and the second semiconductor layer 120B, with the second gate 110B disposed between the first semiconductor layer 120A and the second semiconductor layer 120B. On the other hand, the thin film transistor 1D further includes a third gate 110C and a third gate insulating layer 130C. The third gate 110C is disposed on the second semiconductor layer 120B, and overlaps with the second channel region 122B. The third gate insulating layer 130C is disposed between the third gate 110C and the second semiconductor layer 120B to electrically insulate the two.

Specifically, in the direction Z, the thin film transistor 1D may include the buffer layer 140, the first gate 110A, the first gate insulating layer 130A, the first semiconductor layer 120A, the second gate insulating layer 130B, the second gate 110B, the insulating layer 150, the insulating layer 151, the second semiconductor layer 120B, and the third gate insulating layer 130BC arranged in sequence from the substrate 100 to the blocking layer 160. In this embodiment, the first semiconductor layer 120A and the second semiconductor layer 120B of the thin film transistor 1D may both be electrically controlled by two gates, which may also be interpreted as the thin film transistor 1D including two dual-gate transistors. In other embodiments, the first gate 110A may serve as a wiring for other functions to increase the layout flexibility of the circuit. For example, in some embodiments, the first gate 110A may serve as a shielding layer to provide electrostatic discharge (ESD) protection. According to design requirements, in some embodiments, the first gate 110A may or may not receive a potential (for example, floating connection, ground potential, serving as a common electrode (vcom), source or drain), and connect to external circuits through internal wiring (not illustrated) at other positions in the thin film transistor 1D. The present disclosure is not limited to this.

Please continue to refer to FIG. 6B, the insulating layer 151 may also have a contour similar to that of the first gate insulating layer 130A. Furthermore, the first semiconductor layer 120A, the insulating layer 150, and the insulating layer 151 may all adopt a planarization process similar to that of the aforementioned first gate insulating layer 130A to reduce step differences, so that the upper surface of the insulating layer 151 (i.e., the surface of the insulating layer 151 away from the first gate 110A) may also have a groove GR2. The position of the groove GR2 may overlap with the position of the groove GR1, and have similar characteristics and thickness relationships as the groove GR1 in FIG. 1B mentioned earlier. In other words, the second semiconductor layer 120B above the insulating layer 151, and the first semiconductor layer 120A above the second sublayer 132A may both be formed on a relatively flat surface to improve the electrical properties and yield of the thin film transistor 1D, and the thickness of the first gate 110A and the second gate 110B may not need to be reduced, maintaining their good conductivity. Related content may be referenced to the aforementioned paragraphs, which will not be repeated here.

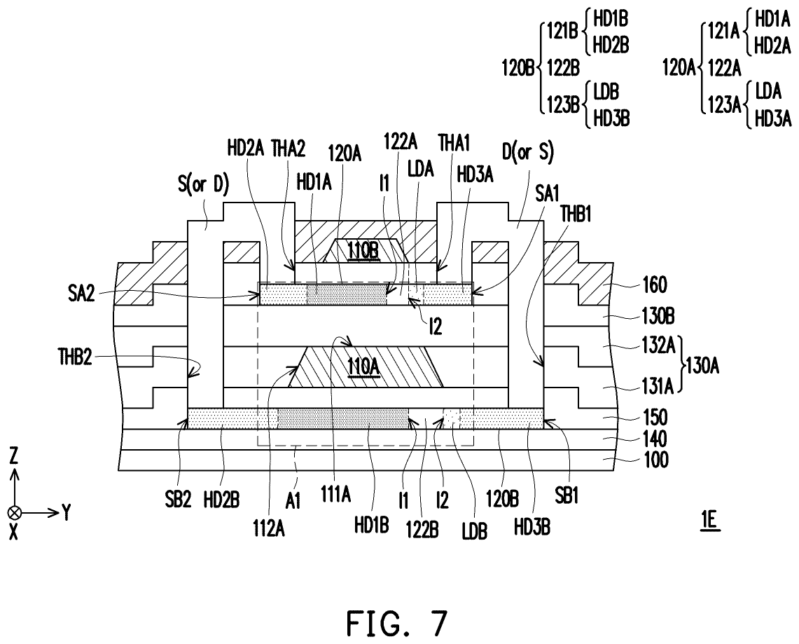

FIG. 7 is a cross-sectional schematic view of a thin film transistor according to an embodiment of the present disclosure. Please refer to FIG. 7, the thin film transistor 1E is similar to the aforementioned thin film transistor 1, with the main difference being: in the thin film transistor 1E, the heavily-doped region of the first semiconductor layer 120A extends into the projection of the second gate 110B, and the heavily-doped region of the second semiconductor layer 120B extends into the projection of the first gate 110A. Specifically, the first source region 121A of the first semiconductor layer 120A may include a first heavily-doped region HD1A and a second heavily-doped region HD2A, and the first drain region 123A may include a lightly-doped region LDA and a third heavily-doped region HD3A. Furthermore, in the direction Y, the first heavily-doped region HD1A is disposed between the second heavily-doped region HD2A and the first channel region 122A, the first channel region 122A is disposed between the first heavily-doped region HD1A and the lightly-doped region LDA, the lightly-doped region LDA is disposed between the first channel region 122A and the third heavily-doped region HD3A, and there is a boundary I2 between the first channel region 122A and the lightly-doped region LDA, and a boundary I1 between the first channel region 122A and the first heavily-doped region HD1A. Moreover, the length of the first heavily-doped region HD1A extends in the direction Y, so that the first heavily-doped region HD1A overlaps with the second gate 110B in the direction Z.

Specifically, the doping concentration of the first heavily-doped region HD1A and the second heavily-doped region HD2A may be selectively different (for example: the doping concentration of the first heavily-doped region HD1A is higher than the doping concentration of the second heavily-doped region HD2A), but the present disclosure is not limited to this. As mentioned before, the boundary I1 and the boundary I2 are not visible, and they are virtual boundaries between two regions with different doping concentrations. By reducing the length of the first channel region 122A in the direction Y (i.e., the horizontal distance between the boundary I1 and the boundary I2 in the direction Y), a carrier channel with a shorter length may be produced, which may increase the on-current flowing through the thin film transistor 1E, enabling the thin film transistor 1E to provide good electrical properties when applied to elements that require high current.

Similarly, the second source region 121B of the second semiconductor layer 120B may include a first heavily-doped region HD1B and a second heavily-doped region HD2B, and the second drain region 123B may include a lightly-doped region LDB and a third heavily-doped region HD3B. Furthermore, in the direction Y, the first heavily-doped region HD1B is disposed between the second heavily-doped region HD2B and the second channel region 122B, the second channel region 122B is disposed between the first heavily-doped region HD1B and the lightly-doped region LDB, the lightly-doped region LDB is disposed between the second channel region 122B and the third heavily-doped region HD3B, and the second channel region 122B and the lightly-doped region LDB also have a boundary I2, while the second channel region 122B and the first heavily-doped region HD1B also have a boundary I1. Moreover, the length of the first heavily-doped region HD1B extends in the direction Y, so that the first heavily-doped region HD1B overlaps with the first gate 110A in the direction Z. The configuration relationship of various doped regions in the second semiconductor layer 120B may be the same as the configuration relationship of the first semiconductor layer 120A, therefore the second semiconductor layer 120B may also have similar characteristics and effects as the first semiconductor layer 120A, which will not be repeated here.

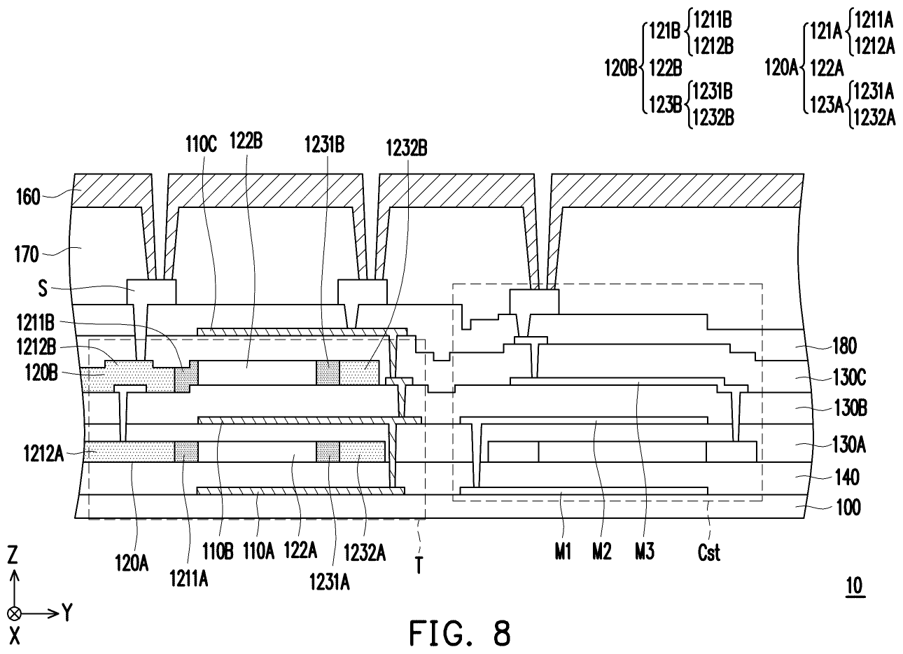

FIG. 8 is a cross-sectional schematic view of a partial region of a pixel structure according to an embodiment of the present disclosure. Referring to FIG. 8, the pixel structure 10 may also include other film layers thereabove, such as a planarization layer 170 and a dielectric layer 180. The dielectric layer 180 may be disposed between the third gate insulating layer 130C and the planarization layer 170, and the planarization layer 170 may be disposed between the dielectric layer 180 and the blocking layer 160. On the other hand, the thin film transistor T may have a structure similar to the aforementioned thin film transistors 1A to 1D, which will not be repeated here. It is worth mentioning that in FIG. 8, the first gate 110A, the second gate 110B, and the third gate 110C in the thin film transistor T may be connected in series with each other. On the other hand, the thin film transistor T may be electrically connected to the capacitor Cst. The capacitor Cst may have a metal layer M1, a metal layer M2, and a metal layer M3, and form the internal structure of the capacitor Cst through the buffer layer 140, the first gate insulating layer 130A, and the second gate insulating layer 130B.

In summary, during the preparation process of the thin film transistor of the present disclosure, due to the flattening of the topography of the gate insulating layer above the gate, while maintaining a certain thickness of the gate metal layer to ensure better electrical performance, the step difference formed by the gate insulating layer thereabove may also be reduced, or the upper surface of the gate insulating layer may be relatively flat. Therefore, the semiconductor layer on the upper surface of the gate insulating layer may also grow on a relatively flat surface, which reduces the probability of disconnection of the semiconductor layer during the process, further improving the performance and the process yield of the thin film transistor.

Although the present disclosure has been disclosed by the above embodiments, it is not intended to limit the present disclosure. Any person of ordinary skill in the relevant technical field may make some modifications and refinements without departing from the spirit and scope of the present disclosure. Therefore, the protection scope of the present disclosure should be defined by the appended claims.

What is claimed is:

1. A thin film transistor, comprising:
a substrate;
a first gate, disposed on the substrate, having a top surface and a side surface connected to the top surface;
a first semiconductor layer, disposed on the substrate, the first semiconductor layer comprising a first drain region, a first channel region and a first source region, and the first gate overlapping with the first channel region; and
a first gate insulating layer, disposed between the first semiconductor layer and the first gate, a contour of an upper surface of the first gate insulating layer having a first surface, a second surface, a third surface and a fourth surface arranged in sequence to form a groove,
wherein the first surface overlaps with the top surface, the second surface and the third surface overlap with the side surface, the fourth surface overlaps with the substrate,
wherein a thickness of the first gate insulating layer on the first surface is less than a thickness of the first gate insulating layer on the second surface, and a thickness of the first gate insulating layer increases from the third surface to the fourth surface.

2. The thin film transistor as claimed in claim 1, further comprising:
a second gate insulating layer, disposed on the first semiconductor layer; and
a second gate, disposed on the second gate insulating layer.

3. The thin film transistor as claimed in claim 2, further comprising:
a second semiconductor layer, disposed on the substrate, wherein the second semiconductor layer comprises a second drain region, a second channel region and a second source region, the second channel region overlapping with the first gate.

4. The thin film transistor as claimed in claim 3, further comprising:
a buffer layer, disposed between the substrate and the second semiconductor layer, wherein the second semiconductor layer is disposed between the substrate and the first gate.

5. The thin film transistor as claimed in claim 4, further comprising:
an insulating layer, disposed between the second semiconductor layer and the first gate, wherein a thickness of the insulating layer is greater than a thickness of the first gate insulating layer on the top surface.

6. The thin film transistor as claimed in claim 3, further comprising:
an insulating layer, disposed between the second gate and the second semiconductor layer, wherein the second gate is disposed between the first semiconductor layer and the second semiconductor layer.

7. The thin film transistor as claimed in claim 6, further comprising:
a third gate, disposed on the second semiconductor layer and overlapping with the second channel region; and
a third gate insulating layer, disposed between the third gate and the second semiconductor layer.

8. The thin film transistor as claimed in claim 7, wherein the first gate, the second gate and the third gate are connected in series with each other.

9. The thin film transistor as claimed in claim 1, wherein a depth of the groove is greater than 0 micrometers and less than half of a thickness of the first gate.

10. The thin film transistor as claimed in claim 1, wherein a thickness of the first gate is greater than 1000 angstroms (Å).

11. The thin film transistor as claimed in claim 3, wherein a depth of the groove is less than a maximum thickness of the second semiconductor layer.

12. The thin film transistor as claimed in claim 3, further comprising:
a drain, directly electrically connected to a first side of the first semiconductor layer and a first side of the second semiconductor layer; and
a source, directly electrically connected to a second side of the first semiconductor layer and a second side of the second semiconductor layer, wherein the first side and the second side of the first semiconductor layer are opposite to each other, and the first side and the second side of the second semiconductor layer are opposite to each other.

13. The thin film transistor as claimed in claim 1, wherein the first gate insulating layer comprises a first sublayer and a second sublayer, the first sublayer is disposed between the first gate and the second sublayer.

14. The thin film transistor as claimed in claim 13, wherein the first sublayer covers the side surface of the first gate, the first sublayer forms a concave structure on the side surface of the first gate, and the concave structure overlaps with the groove.

15. The thin film transistor as claimed in claim 14, wherein the second sublayer contacts a part of the top surface of the first gate, the concave structure, and an upper surface of the first sublayer.

16. The thin film transistor as claimed in claim 1, wherein the first semiconductor layer has a first heavily-doped region, a second heavily-doped region, a third heavily-doped region, and a lightly-doped region, wherein the first heavily-doped region is disposed between the second heavily-doped region and the first channel region, the first channel region is disposed between the first heavily-doped region and the lightly-doped region, the lightly-doped region is disposed between the first channel region and the third heavily-doped region, and there is a boundary between the first channel region and the lightly-doped region.

17. The thin film transistor as claimed in claim 3, wherein the second semiconductor layer has a first heavily-doped region, a second heavily-doped region, a third heavily-doped region, and a lightly-doped region, wherein the first heavily-doped region is disposed between the second heavily-doped region and the second channel region, the second channel region is disposed between the first heavily-doped region and the lightly-doped region, the lightly-doped region is disposed between the second channel region and the third heavily-doped region, and there is a boundary between the channel region and the lightly-doped region.

18. A pixel structure, comprising:
a self-luminous element; and
a plurality of thin film transistors, wherein at least one of the thin film transistors has a structure of the thin film transistor as claimed in claim 1, wherein the at least one of the thin film transistors is electrically connected to the self-luminous element, and the self-luminous element comprises at least one of a micro light-emitting diode, a sub-millimeter light-emitting diode, and an organic light-emitting diode.

19. The pixel structure as claimed in claim 18, wherein the at least one of the thin film transistors is a driving thin film transistor or a light-emitting thin film transistor.

20. The pixel structure as claimed in claim 18, wherein at least another one of the thin film transistors is a switching thin film transistor, and three terminals of the switching thin film transistor are respectively electrically connected to a data line, a scan line, and the at least one of the thin film transistors.

21. A method of manufacturing a thin film transistor, comprising:
forming a gate on a substrate, having a top surface and a side surface connected to the top surface;
forming a gate insulating layer on the gate;
etching the gate insulating layer, so that a contour of an upper surface of the gate insulating layer has a first surface, a second surface, a third surface, and a fourth surface arranged in sequence to form a groove; and
forming a semiconductor layer, so that the gate insulating layer is disposed between the semiconductor layer and the gate, wherein the first surface overlaps the top surface, the second surface and the third surface overlap the side surface, and the fourth surface overlaps the substrate,
wherein a thickness of the gate insulating layer on the first surface is less than a thickness of the gate insulating layer on the second surface, and a thickness of the gate insulating layer increases from the third surface to the fourth surface.
